(19) United States
(12) Patent Application Publication
(10) Pub. No.: US 2026/0190843 A1
(43) Pub. Date: Jul. 2, 2026

(54) Display Device

(71) Applicant: LG Display Co., Ltd., Seoul (KR)

(72) Inventor: Juyeon Won, Gimpo-si (KR)

(21) Appl. No.: 19/428,945

(22) Filed: Dec. 22, 2025

(30) Foreign Application Priority Data
Dec. 31, 2024 (KR) 10-2024-0202045

(51) Int. Cl. H10K 59/80; H10K 59/122; H10K 59/124; H10K 59/131

(52) U.S. Cl. CPC H10K 59/8794; H10K 59/122; H10K 59/124; H10K 59/131; H10K 59/80521; H10K 59/873

(57) ABSTRACT

According to an aspect of the present disclosure, a display device includes a substrate including a display area and a non-display area outside the display area, a planarization layer disposed over the substrate and extending from the display area to the non-display area, a bank disposed over the planarization layer and extending to the non-display area, a protection layer disposed over the bank, an adhesive layer disposed over the protection layer and disposed in the adhesive layer along at least one edge of the encapsulation substrate and the non-display area, and a heat transfer member extending from an upper surface of the substrate to the encapsulation substrate and transferring heat, thereby improving heat dissipation efficiency.

### CROSS-REFERENCE TO RELATED APPLICATIONS

This application claims the priority under 35 U.S.C. §119(a) to the Republic of Korea Patent Application No. 10-2024-0202045 filed on December 31, 2024, the entire contents of which are hereby expressly incorporated by reference into the present application.

### TECHNICAL FIELD

The present disclosure relates to a display device, and more particularly, to a display device capable of controlling heat dissipation.

### BACKGROUND

Currently, as it enters a full-fledged information era, the field of display devices that visually display electrical information signals is rapidly developing, and research is being continuously conducted to develop performances such as thinning, weight reduction, and low power consumption for various display devices.

Representative display devices include a liquid crystal display (LCD), an electro-wetting display (EWD), and an organic light emitting display (OLED).

Among them, an electroluminescent display device including an organic light emitting display device is a self-emitting display device and does not require a separate light source unlike a liquid crystal display device, and thus may be manufactured to have a light weight and a small thickness. In addition, the electroluminescent display device is advantageous not only in terms of power consumption due to low voltage driving, but also in terms of color representation, response speed, viewing angle, and contrast ratio, so that it is expected to be used in various fields.

In the display device, a region in which wirings and electrodes are densely disposed, such as a pad part, may generate relatively high heat. In particular, heat generation occurs more significantly in high luminance models, and if heat generation is not sufficiently controlled, the lifespan of the light emitting element may be shortened.

### SUMMARY

An object to be achieved by the present disclosure is to provide a display device capable of preventing deterioration in lifespan of a light emitting element by effectively controlling heat generated from a panel.

Another object to be achieved by the present disclosure is to provide a display device capable of improving the performance and reliability of a large display panel by solving a heat generation problem.

Objects of the present disclosure are not limited to the above-mentioned objects, and other objects, which are not mentioned above, can be clearly understood by those skilled in the art from the following descriptions.

A display device according to an exemplary embodiment of the present disclosure may include a substrate including a display area and a non-display area outside the display area, a planarization layer disposed over the substrate and extending from the display area to the non-display area, a bank disposed over the planarization layer and extending to the non-display area, a protection layer disposed over the bank, an adhesive layer disposed over the protection layer and disposed in the adhesive layer along at least one edge of the encapsulation substrate and the non-display area, and a heat transfer member extending from an upper surface of the substrate to the encapsulation substrate for transferring heat.

Other detailed matters of the embodiments are included in the detailed description and the drawings.

According to the present disclosure, a heating generating portion such as a pad part is brought into contact with an encapsulation substrate through a heat transfer member having high thermal conductivity to effectively transfer the generated heat to the encapsulation substrate, thereby improving heat dissipation efficiency. Accordingly, it is possible to maintain a stable temperature even in high luminance display panels, and it is possible to contribute to extending the lifespan of the display device by preventing deterioration of the light emitting element. In addition, by improving the heat dissipation, it is possible to realize high luminance and improve the stability of the panel, and it provides an effect of increasing production efficiency by minimizing quality defects due to heat generation.

The effects according to the present disclosure are not limited to the contents exemplified above, and more various effects are included in the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a plan view of a display device according to a first embodiment of the present disclosure.

FIG. 2 is a cross-sectional view of a sub-pixel of the display device of FIG. 1.

FIG. 3 is a view illustrating a part of a cross-section of the display device of FIG. 1 according to I-I′.

FIG. 4 is a plan view of a display device according to a second embodiment of the present disclosure.

FIG. 5 is a cross-sectional view taken along the line IIa-IIa′ of the display device of FIG. 4.

FIG. 6 is a cross-sectional view taken along the line IIb-IIb’ of the display device of FIG. 4.

FIG. 7 is a cross-sectional view of a display device according to a third embodiment of the present disclosure.

FIG. 8 is a cross-sectional view of a display device according to a fourth embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, exemplary embodiments of the present disclosure will be described in detail with reference to accompanying drawings.

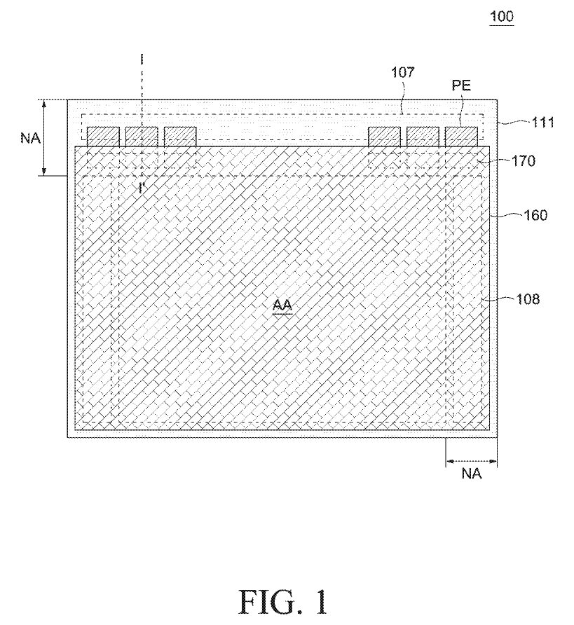

FIG. 1 is a plan view of a display device according to a first embodiment of the present disclosure.

Referring to FIG. 1, a display device 100 according to a first embodiment of the present disclosure may include a substrate 111, an encapsulation substrate 160, and pad parts 107 and 108.

The display device 100 is a device for displaying an image to a user.

The display device 100 may include a display element for displaying images, a driving element for driving the display element, and wirings for transmitting various signals to the display element and the driving element. The display element may be differently defined depending on the type of the display device 100, and for example, when the display device 100 is an organic light emitting display device, the display element may be an organic light emitting element including an anode, an organic light emitting layer, and a cathode. For example, when the display device 100 is a liquid crystal display device, the display element may be a liquid crystal display element.

Hereinafter, even though it is assumed that the display device 100 is an organic light emitting display device, the display device 100 is not limited to the organic light emitting display device.

The display device 100 may include a display area AA and a non-display area NA.

The display area AA is an area in which images are displayed in the display device 100.

In the display area AA, a plurality of sub-pixels constituting a plurality of pixels and a circuit for driving the plurality of sub-pixels may be disposed. The plurality of sub-pixels is minimum units constituting the display area AA, and a display element may be disposed in each of the plurality of sub-pixels, and the plurality of sub-pixels may constitute a pixel. For example, an organic light emitting element including an anode, an organic emission layer, and a cathode may be disposed in each of the plurality of sub-pixels, but it is not limited thereto. Further, a circuit for driving the plurality of sub-pixels may include a driving element, a wiring, and the like. For example, the circuit may be formed of a thin film transistor, a storage capacitor, a gate line, a data line, or the like, but is not limited thereto.

The non-display area NA is an area where no image is displayed.

FIG. 1 illustrates that the non-display area NA encloses the display area AA having a rectangular shape. However, the shapes and arrangements of the display area AA and the non-display area NA are not limited to the example illustrated in FIG. 1.

In other words, the display area AA and the non-display area NA may have shapes suitable for the design of an electronic device equipped with the display device 100. For example, an exemplary shape of the display area AA may be a pentagon, a hexagon, a circle, or an oval.

In the non-display area NA, various wirings and circuits for driving the organic light emitting element of the display area AA may be disposed. For example, in the non-display area NA, link lines for transmitting signals to the plurality of sub-pixels and circuits of the display area AA, driving ICs such as gate driver ICs and data driver ICs or pad parts 107 and 108 may be disposed, but are not limited thereto.

The display device 100 may include various additional elements for generating various signals or driving pixels in the display area AA. The additional elements for driving the pixels may include an inverter circuit, a multiplexer, an electrostatic discharge (ESD) circuit, and the like. The display device 100 may also include additional elements related to functions other than pixel driving. For example, the display device 100 may include additional elements that provide a touch sensing function, a user authentication function (e.g., fingerprint recognition), a multi-level pressure sensing function, a tactile feedback function, and the like. The above-mentioned additional elements may be located in the non-display area NA and/or an external circuit connected to the connection interface.

The pad parts 107 and 108 may be disposed to receive a signal from the outside.

The pad parts 107 and 108 may be disposed in the non-display area NA of the display device 100 to be electrically connected to various wirings and printed circuit boards disposed in the display area AA.

For example, the pad parts 107 and 108 may function to transmit a signal to each of the gate line and the data line, and include a gate pad part 108 to transmit a gate signal to the gate line and a data pad part 107 to transmit a data signal to the data line, but are not limited thereto.

The data pad part 107 may be disposed on one side of the display device 100, for example, in the non-display area NA on a first side of the display device 100, but is not limited thereto. For example, the first side may mean an upper side of the display device 100.

The gate pad part 108 may be disposed in the non-display area NA on at least another side of the display device 100, for example, a second side of the display device 100, but is not limited thereto. For example, the second side may refer to the left and right sides of the display device 100 adjacent to the upper and lower sides.

For example, the data pad part 107 may be electrically connected to a data driver to supply the data voltage to a plurality of data lines. The data driver may receive image data from the timing controller and supply the data voltage to the plurality of data lines to drive the plurality of data lines. The data driver may be implemented by including one or more source driver integrated circuits.

For example, each source driver integrated circuit may include a shift register, a latch circuit, a digital to analog converter (DAC), an output buffer, and the like. The data driver may further include one or more analog to digital converters (ADCs), in some cases.

Meanwhile, the gate driver may drive a plurality of gate lines by outputting a scan signal to the plurality of gate lines. For example, the gate driver may sequentially drive the plurality of gate lines by sequentially supplying scan signals to the plurality of gate lines. The gate driver may sequentially supply scan signals of an on voltage or an off voltage to the plurality of gate lines under the control of the timing controller.

The gate driver may include a plurality of gate driving circuits. Here, the plurality of gate driving circuits may correspond to the plurality of gate lines, respectively.

For example, each gate driving circuit may include a shift register, a level shifter, and the like.

Each gate driving circuit may be implemented in a gate-in-panel (GIP) type and embedded in the display device 100. For example, each gate driving circuit may be directly disposed on the gate pad part 108.

Meanwhile, in order to improve the heat dissipation performance of the display device, it is necessary to apply a material having high thermal conductivity. When measuring the panel temperature, significant heat generation is measured in the data pad part where various wirings and electrodes are relatively densely arranged.

In addition, in general, a large amount of heat is generated in a high-luminance model, and when the heat generation is large, deterioration of the lifespan of the light-emitting element is caused, so that it is necessary to control the heat generation.

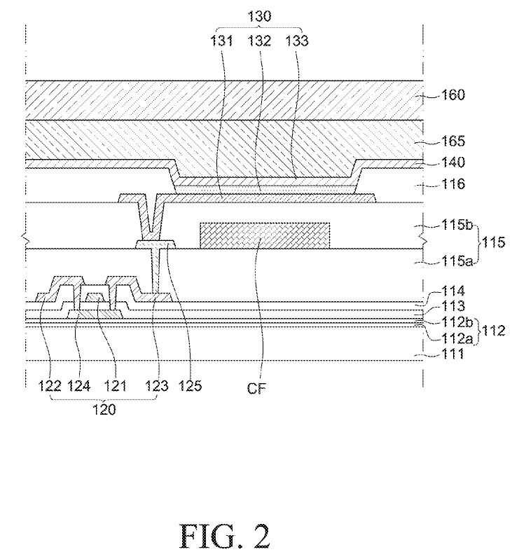

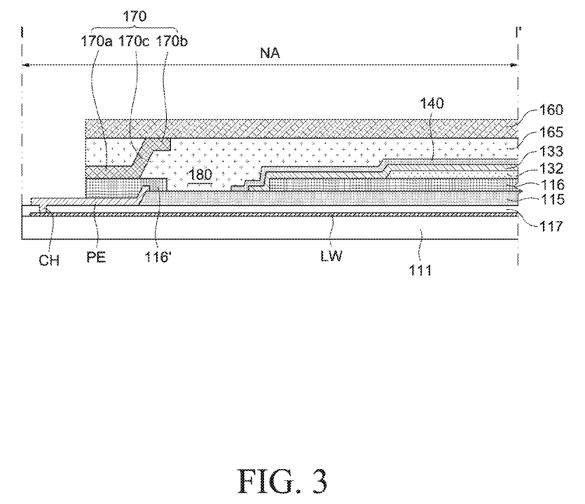

Accordingly, in the display device 100 according to the first embodiment of the present disclosure, a heat transfer member 170 having high thermal conductivity is disposed on the data pad part 107 to effectively transfer heat generated from a pad electrode PE to the encapsulation substrate 160 through the heat transfer member 170, which is characterized in that it will be described in detail with reference to FIGS. 2 and 3.

FIG. 2 is a cross-sectional view of a sub-pixel of the display device of FIG. 1.

FIG. 3 is a view illustrating a part of a cross-section of the display device of FIG. 1 according to I-I′.

FIG. 3 illustrates a part of the non-display area NA on the first side of the display device 100 of FIG. 1.

For example, the first side may mean an upper side of the display device 100.

In FIG. 3, for the convenience of description, at least some of a buffer layer 112, a gate insulating layer 113, and an interlayer insulating layer 114 are illustrated as an insulating layer 117.

Referring to FIGS. 2 and 3, in the display device 100 of the first embodiment of the present disclosure, a driving element 120 may be disposed over the substrate 111.

Further, a planarization layer 115 may be disposed over the driving element 120.

Further, the light emitting element 130 electrically connected to the driving element 120 may be disposed over the planarization layer 115, and a protection layer 140 may be disposed on the light emitting element 130.

An adhesive layer 165 and the encapsulation substrate 160 may be sequentially disposed over the protective layer 140. However, the display device 100 according to the first embodiment of the present disclosure is not limited to this laminated structure.

Meanwhile, the heat transfer member 170 of the first embodiment of the present disclosure may be provided at an edge of the first side non-display area NA between the substrate 111 and the encapsulation substrate 160.

The substrate 111 may be a glass or plastic substrate. In the case of a plastic substrate, a polyimide-based or polycarbonate-based material may be used to have flexibility. In particular, polyimide is a material that can be applied to a high-temperature process and can be coated, so it is widely used as a plastic substrate.

A buffer layer 112 may be disposed on the substrate 111.

Meanwhile, although not illustrated, a light shielding layer may be disposed on the substrate 111 to block light introduced from a lower portion of the substrate 111.

The light shielding layer may be disposed on the substrate 111 at a position where an active layer 124 is to be formed. In particular, it is preferable that the size of the light shielding layer is slightly larger so as to completely cover the active layer 124.

The buffer layer 112 may be disposed on the entire surface of the substrate 111 on which the light shielding layer is formed.

The buffer layer 112 is a layer for protecting various electrodes and wirings from impurities such as alkali ions discharged from the substrate 111 or the underlying layers. The buffer layer 112 may have a multilayer structure including a first buffer layer 112a and a second buffer layer 112b, but is not limited thereto. For example, the buffer layer 112 may be made of silicon oxide (SiOₓ), silicon nitride (SiNₓ), or a multi-layer thereof.

The buffer layer 112 may delay diffusion of moisture and/or oxygen permeating the substrate 111. In addition, the buffer layer 112 may include a multi-buffer and/or an active buffer. The active buffer protects the active layer 124 made of the semiconductor of the driving element 120 and may perform a function of blocking various types of defects introduced from the substrate 111. The active buffer may be formed of amorphous silicon (a-Si) or the like.

Meanwhile, in the non-display area NA, various wirings and circuits for driving the light emitting element 130 of the display area AA may be disposed. For example, in the non-display area NA, a link line LW for transmitting signals to the plurality of sub-pixels and various circuits of the display area AA, a driving IC, such as a gate driver IC or a data driver IC, or a pad part may be disposed, but is not limited thereto.

For example, a ground wiring may be disposed on the substrate 111 in the non-display area NA.

The ground wiring may be disposed at and outermost edge of the non-display area NA excluding the first side.

The link line LW may be disposed above the substrate 111 of the non-display area NA on the first side.

In this case, the link line LW may be formed of a material constituting the light shielding layer and/or the driving element 120 of the display area AA, but is not limited thereto.

In addition, a low potential power line shorting bar may be disposed in the non-display area NA on the second side.

The driving element 120 may include an active layer 124, a gate insulating layer 113, a gate electrode 121, an interlayer insulating layer 114, a source electrode 122, and a drain electrode 123. Further, the driving element 120 may be electrically connected to the light emitting element 130 through a connection electrode 125 to transmit a current or a signal to the light emitting element 130. In addition to the illustrated top gate structure, the driving element 120 may be applied in various ways, such as a bottom gate structure in which the gate electrode is located below the active layer and a coplanar structure in which the gate electrode, the source electrode, and the drain electrode are disposed on the same plane.

The active layer 124 may be positioned on the buffer layer 112. The active layer 124 may be made of polysilicon (p-Si), and in this case, a predetermined region may be doped with impurities. Further, the active layer 124 may be made of amorphous silicon (a-Si) and may be made of an organic semiconductor material such as pentacene. Further, the active layer 124 may be formed of an oxide semiconductor.

The gate insulating layer 113 may be positioned on the active layer 124. For example, the gate insulating layer 113 may be formed of an insulating inorganic material such as silicon oxide (SiOₓ) or silicon nitride (SiNₓ), or an insulating organic material.

The gate electrode 121 may be positioned on the gate insulating layer 113. For example, the gate electrode 121 may be made of various conductive materials, such as magnesium (Mg), aluminum (Al), nickel (Ni), chromium (Cr), molybdenum (Mo), tungsten (W), gold (Au), or an alloy thereof.

The interlayer insulating layer 114 may be positioned on the gate electrode 121. For example, the interlayer insulating layer 114 may be formed of an insulating material such as silicon oxide (SiOₓ) or silicon nitride (SiNₓ), or an insulating organic material.

A contact hole through which the source and drain regions are exposed may be formed by selective removal of the gate insulating layer 113 and the interlayer insulating layer 114. The source electrode 122 and the drain electrode 123 may be formed on the interlayer insulating layer 114 in a single layer or a multi-layered structure using an electrode material.

If necessary, an additional protective layer made of an inorganic insulating material may be formed to cover the source electrode 122 and the drain electrode 123.

Meanwhile, at least some of the buffer layer 112, the gate insulating layer 113, and the interlayer insulating layer 114, i.e., the insulating layer 117, may extend to the non-display area NA.

The planarization layer 115 may be disposed over the driving element 120 configured as described above.

The planarization layer 115 may have a multilayer structure including at least two layers. For example, referring to FIG. 2, the planarization layer 115 may include a first planarization layer 115a and a second planarization layer 115b, but is not limited thereto.

For example, the first planarization layer 115a is disposed to cover the driving element 120 and may be disposed to expose a part of the source electrode 122 or the drain electrode 123 of the driving element 120.

The planarization layer 115 may extend to the non-display area NA.

The planarization layer 115 may be an overcoat layer, but is not limited thereto.

The connection electrode 125 for electrically connecting the driving element 120 and the light emitting element 130 may be disposed over the first planarization layer 115a. In addition, although not illustrated in FIG. 2, various metal layers serving as wirings/electrodes such as data lines and signal lines may be disposed on the first planarization layer 115a.

Further, a color filter CF may be disposed on the first planarization layer 115a. However, the present disclosure is not limited thereto. The color filter CF may be omitted depending on the type of the light emitting element 130.

The color filter CF of each sub-pixel may have any one of red, green, and blue colors. In addition, in the case of a sub-pixel in which white is implemented, the color filter CF may not be disposed. The arrangement of red, green, and blue may be variously formed, and a black matrix capable of absorbing external light may be provided between the color filters CF.

In the case of the bottom emission type, the color filter CF may be located under the anode 131.

Further, the second planarization layer 115b may be disposed on the first planarization layer 115a and the connection electrode 125. The planarization layer 115 of the first embodiment of the present disclosure is composed of two layers due to an increase in various signal lines as the display device 100 has a high resolution. Accordingly, it is difficult to dispose all wirings on one layer while securing a minimum gap, so an additional layer is formed. The addition of the additional layer (i.e., the second planarization layer 115b) may provide room for wiring arrangement, which may make it easier to design wiring/electrode arrangement. In addition, when a dielectric material is used as the planarization layer 115 configured as a multilayer, it may be used for forming capacitance between metal layers.

The second planarization layer 115b may be formed to expose a part of the connection electrode 125. Further, the drain electrode 123 of the driving element 120 and the anode 131 of the light emitting element 130 may be electrically connected by the connection electrode 125.

In this case, the light emitting element 130 may be configured such that the anode 131, a plurality of organic layers 132, and the cathode 133 are sequentially disposed. That is, the light emitting element 130 may include the anode 131 disposed on the planarization layer 115, the organic layer 132 disposed on the anode 131, and the cathode 133 disposed on the organic layer 132.

The display device 100 may be implemented in a top emission type or a bottom emission type. In the top emission type, a reflective layer made of an opaque conductive material having high reflectivity, for example, silver (Ag), aluminum (Al), gold (Au), molybdenum (Mo), tungsten (W), chromium (Cr), or an alloy thereof, may be added under the anode 131 so that light emitted from the organic layer 132 is reflected by the anode 131 and directed upward, that is, in the direction of the cathode 133 at the top. Conversely, in the case of the bottom emission type, the anode 131 may be made of only a transparent conductive material such as indium tin oxide (ITO), indium zinc oxide (IZO), indium gallium zinc oxide (IGZO). Hereinafter, the present disclosure will be made on the assumption that the display device 100 is a bottom emission type. However, the present disclosure is not limited thereto.

A bank 116 may be formed on the planarization layer 115 in a region other than an emission region. That is, the bank 116 may have a bank hole exposing the anode 131 corresponding to the emission area. The bank 116 may be made of an inorganic insulating material such as silicon nitride (SiNₓ) or silicon oxide (SiOₓ), or an organic insulating material such as BCB, acrylic resin, or imide resin.

The bank 116 may extend to the non-display area NA.

The organic layer 132 may be disposed on the anode 131 exposed by the bank 116. The organic layer 132 may include an emission layer, an electron injection layer, an electron transport layer, a hole transport layer, a hole injection layer, and the like.

The organic layer 132 may extend to the non-display area NA.

The cathode 133 may be disposed on the organic layer 132.

In the case of the top emission type, the cathode 133 may include a transparent conductive material. For example, the cathode 133 may be formed of indium tin oxide (ITO), indium zinc oxide (IZO), indium gallium zinc oxide (IGZO), or the like. In the case of the bottom emission type, the cathode 133 may include any one of a group formed of a metal material such as gold (Au), silver (Ag), aluminum (Al), molybdenum (Mo), magnesium (Mg), palladium (Pd), copper (Cu) or an alloy thereof. Alternatively, the cathode 133 may be configured by laminating a layer made of a transparent conductive material such as indium tin oxide (ITO), indium zinc oxide (IZO), indium gallium zinc oxide (IGZO), and a layer made of a metal material such as gold (Au), silver (Ag) aluminum (Al), molybdenum (Mo), magnesium (Mg), palladium (Pd), copper (Cu), or an alloy thereof, but is not limited thereto.

The cathode 133 may extend to the non-display area NA.

Although not illustrated, a capping layer may be disposed on the cathode 133. The capping layer may be formed of a material having a high refractive index and a high light absorption rate to reduce diffused reflection of external light.

The protective layer 140 may be disposed over the light emitting element 130 configured as described above.

The protective layer 140 may be an inorganic layer, and in this case, may be made of silicon oxide (SiOₓ), silicon nitride (SiNₓ), or a multi-layer thereof.

The protective layer 140 may extend to the non-display area NA.

The adhesive layer 165 and the encapsulation substrate 160 may be disposed over the protection layer 140.

However, the present disclosure is not limited thereto, and an encapsulation structure of a multilayer structure composed of a sealing member and a reinforcing substrate may be disposed on the protection layer 140.

The adhesive layer 165 may be disposed between the protective layer 140 and the encapsulation substrate 160.

For example, the adhesive layer 165 may serve to delay lateral moisture permeation.

For example, the adhesive layer 165 may further include a moisture absorbent such as a getter in addition to isobutyl rubber resin. The moisture absorbent may include calcium oxide.

The moisture absorbent may be particles having hygroscopicity and absorb moisture and oxygen from the outside to minimize the penetration of moisture and oxygen into the display area AA.

The encapsulation substrate 160 may be disposed on the adhesive layer 165.

The encapsulation substrate 160, together with the adhesive layer 165, may protect the light emitting element 130 from external moisture, oxygen, impact, and the like.

For example, the encapsulation substrate 160 may serve to prevent front moisture permeation.

For example, the encapsulation substrate 160 may be made of steel use stainless (SUS) or Invar, but is not limited thereto. At this time, Invar is one of the alloys consisting of nickel and iron, and has a very low coefficient of thermal expansion and is relatively stable against temperature changes.

In the non-display area NA, at least some layers of the insulating layer 117, that is, the buffer layer 112, the gate insulating layer 113, and the interlayer insulating layer 114 may extend. For example, the insulating layer 117 extending to the non-display area NA may extend to an end of the substrate 111, but is not limited thereto.

For example, the link line LW may be disposed on the substrate 111 in the non-display area NA.

The link line LW may extend from the display area AA to an end of the non-display area NA on the first side.

A plurality of link lines LW may be provided.

That is, the link lines LW may be disposed in a number corresponding to the number of signal lines. For example, in a resolution of 1024×768, the link lines LW may be disposed in a number corresponding to the number of horizontal pixels (horizontal resolution), that is, 1024, but is not limited thereto.

In addition, the link line LW may be formed of a conductive material constituting the light shielding layer and/or the driving element 120 of the display area AA, but is not limited thereto.

For example, the link line LW includes a lower layer link line and an upper layer link line, and the upper layer link line may be electrically connected to the lower layer link line through a contact hole. Further, for example, the lower layer link line may be made of a material constituting a light shielding layer, and the upper layer link line may be made of a material constituting a gate electrode, but is not limited thereto.

In addition, the link line LW may be disposed side by side in one direction, but is not limited thereto, and may be disposed in a zigzag shape or may be disposed to be inclined at a predetermined angle. In addition, some of the link lines LW may be disposed side by side in one direction, and some of the other link lines LW may be disposed in a zigzag shape or inclined at a predetermined angle. In addition, a part of the link line LW may be disposed side by side in one direction, and the other part may be disposed in a zigzag shape or inclined at a predetermined angle.

At least some layers of the insulating layer 117, that is, the buffer layer 112, the gate insulating layer 113, and the interlayer insulating layer 114 may be disposed over the link line LW.

A part of the link line LW may be exposed through the contact hole CH at an end of the substrate 111. That is, a contact hole CH exposing a part of the link line LW under the insulating layer 117 extending to the non-display area NA may be formed by selectively removing a portion of the insulating layer 117.

The contact hole CH may be disposed so as to correspond to the link line LW.

Further, the planarization layer 115 may extend to the non-display area NA.

For example, the planarization layer 115 may extend to the non-display area NA so as to be spaced apart from the end of the substrate 111 by a predetermined distance, but is not limited thereto. Further, for example, the planarization layer 115 may extend to the non-display area NA so as to be spaced apart from the adhesive layer 165 and the end of the encapsulation substrate 160 by a predetermined distance, but is not limited thereto.

The pad electrode PE may be disposed on the insulating layer 117 at an end of the substrate 111.

For example, the pad electrode PE may extend from the data pad part 107 of FIG. 1 toward the display area AA of FIG. 1. For example, the pad electrode PE may be disposed to extend to the end of the planarization layer 115 and may be in contact with the side portion of the planarization layer 115, but is not limited thereto.

For example, the pad electrode PE may be formed on the same layer with the same conductive material forming the anode 131 of the display area AA, but is not limited thereto.

The pad electrode PE may be electrically connected to the link line LW through the contact hole CH. To this end, the pad electrode PE may be disposed so as to correspond to the link line LW. That is, the pad electrodes PE may be disposed as many as the number of link lines LW.

The bank 116 may extend to the non-display area NA so as to be spaced apart from the end of the planarization layer 115 by a predetermined distance.

Meanwhile, a part of the bank 116 may form an outer bank 116′ that covers an inner end portion of the pad electrode PE in an island shape. Meanwhile, the bank 116 and the outer bank 116′ may be separated and disposed on both sides with respect to a trench 180.

For example, the trench 180 may be disposed in the other direction perpendicular to one direction in which the link line LW is disposed at the edge of the non-display area NA, but is not limited thereto.

For example, the outer bank 116′ may extend from the end portions of the adhesive layer 165 and the encapsulation substrate 160 to cover the inner end portion of the pad electrode PE.

Meanwhile, in the non-display area NA, the organic layer 132 may be disposed on the bank 116.

The organic layer 132 extends to the non-display area NA, and an end portion of the organic layer 132 may be disposed inside compared to an end portion of the bank 116, but is not limited thereto.

In the non-display area NA, the cathode 133 may be disposed on the organic layer 132.

For example, the cathode 133 may extend into the trench 180 to cover the end portion of the bank 116, but is not limited thereto.

For example, the cathode 133 may extend into the trench 180 to cover the bank 116 and the organic layer 132 inside the trench 180.

The cathode 133 may be in contact with the upper surface of the planarization layer 115 exposed by the trench 180.

In addition, the protective layer 140 may extend into the trench 180 to cover the cathode 133, but is not limited thereto. For example, the protective layer 140 may extend into the trench 180 to surround the cathode 133.

For example, the protective layer 140 may be made of an inorganic insulating material.

The protective layer 140 may delay moisture permeation at the top and suppress the occurrence of defects due to dents or foreign substances.

The protective layer 140 may be made of silicon oxide (SiOₓ), silicon nitride (SiNₓ), or a multi-layered structure thereof to delay moisture permeation, but is not limited thereto.

The encapsulation substrate 160 may be disposed on the protection layer 140 with an adhesive layer 165 interposed therebetween.

Meanwhile, in the display device 100 according to the first embodiment of the present disclosure, configured as described above, is characterized in that the heat transfer member 170 is disposed at the edge of the non-display area NA on the first side.

In the sealing structure of a large-sized display panel, heat generated from the pad part on the substrate is dissipated through the upper encapsulation substrate. However, the material used for the adhesive layer has very low thermal conductivity compared to the metal of the encapsulation substrate, so it is difficult to effectively transfer heat generated from the substrate side to the encapsulation substrate. For reference, it can be seen that the thermoelectric conductivity of the SUS or Invar of the encapsulation substrate is about 27 W/m-K and 11 W/m-K, while the thermoelectric conductivity of the adhesive layer is very low at about 0.19 W/m-K.

Accordingly, in the display device 100 according to the first embodiment of the present disclosure is characterized in that the heat transfer member 170 having high thermal conductivity is disposed over the data pad part 107 to effectively transfer heat generated from the pad electrode PE to the encapsulation substrate 160 through the heat transfer member 170. Accordingly, it is possible to maintain a stable temperature even in the high luminance display panel, and by preventing deterioration of the light emitting element 130, it is possible to contribute to extending the lifespan of the display device 100. In addition, by improving the heat dissipation, it is possible to realize high luminance and improve the stability of the panel, and it provides an effect of increasing production efficiency by minimizing quality defects due to heat generation.

For example, the heat transfer member 170 may be disposed at an edge of the first side non-display area NA between the substrate 111 and the encapsulation substrate 160.

For example, a plurality of heat transfer members 170 may be disposed along the data pad part 107 of the first side non-display area NA, where a relatively large amount of heat is generated.

The heat transfer member 170 may be configured by any one of gold (Au), silver (Ag), copper (Cu), aluminum (Al), titanium (Ti), molybdenum-titanium alloy (MoTi), and nickel (Ni) to effectively transfer heat generated from the pad electrode PE of the data pad part 107 to the encapsulation substrate 160, but is not limited thereto. For reference, it can be seen that the thermoelectric conductivity of aluminum and copper is very high at about 170 W/m-K and 401 W/m-K.

The heat transfer member 170 according to the first embodiment of the present disclosure may include a first portion 170a disposed on the outer bank 116' and configured to adjoin the outer bank 116', a second portion 170b disposed below the encapsulation substrate 160 and configured to adjoin the encapsulation substrate 160, and a connection part 170c disposed in the adhesive layer 165 and configured to connect the first portion 170a and the second portion 170b, but is not limited thereto.

For example, the first portion 170a may be disposed to overlap the pad electrode PE.

Further, the first portion 170a may be disposed on the outer bank 116' and a lower surface of the first portion 170a may be substantially parallel to the upper surface of the outer bank 116'.

The connection part 170c may extend from the first portion 170a so that the surface thereof may have a predetermined angle with respect to the outer bank 116′ thereof.

Although not shown, the connection part 170c may have a zigzag shape.

The second portion 170b may extend from the connection part 170c, be disposed below the encapsulation substrate 160, and a top surface of the second portion 170b may be substantially parallel to the bottom surface of the encapsulation substrate 160.

The first portion 170a, the second portion 170b, and the connection part 170c of the heat transfer member 170 may be integrally formed, but are not limited thereto.

Meanwhile, according to the present disclosure, a heat transfer member may be added to and disposed in a non-display area on an opposite side to the non-display area on the first side where the data pad part is located, and this will be described in detail with reference to the drawings.

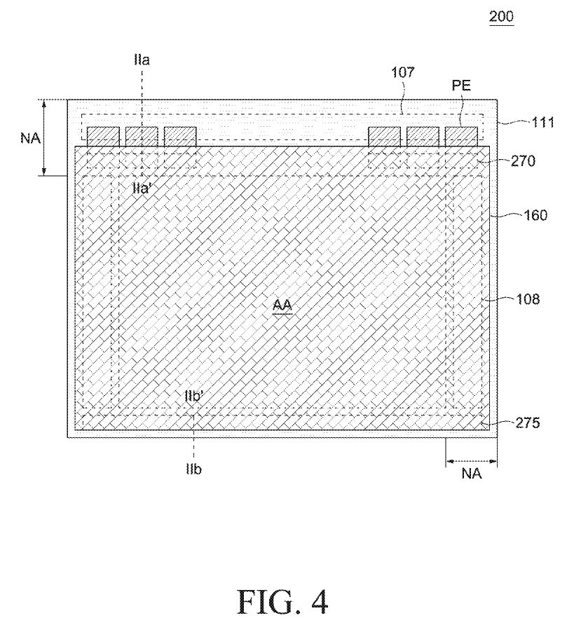

FIG. 4 is a plan view of a display device according to a second embodiment of the present disclosure.

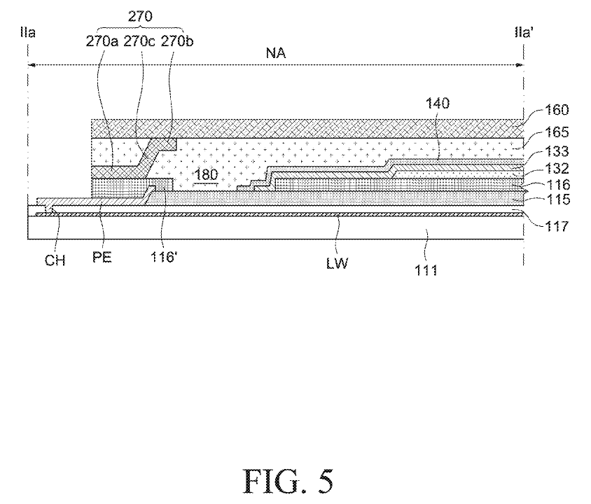

FIG. 5 is a cross-sectional view taken along a line IIa-IIa′ of the display device of FIG. 4.

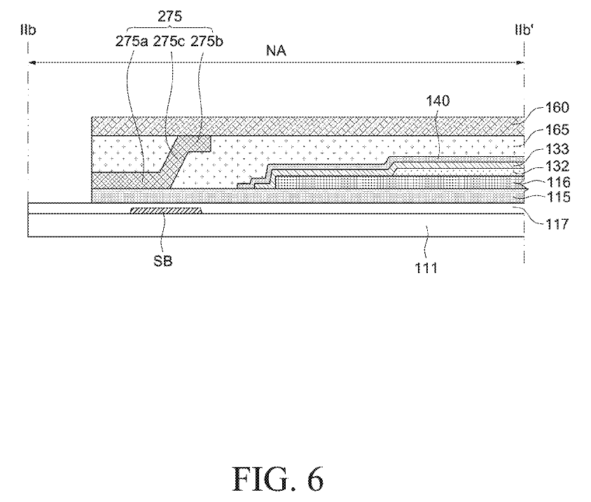

FIG. 6 is a cross-sectional view taken along the line IIb-IIb’ of the display device of FIG. 4.

In the display device 200 of the second embodiment of FIGS. 4 to 6, only the configurations of the heat transfer members 270 and 275 are different from those of the first embodiment of FIGS. 1 to 3 described above, and other configurations are substantially the same, so that a redundant description will be omitted. The same components will be denoted by the same reference numerals. Hereinafter, description of the same reference numerals may refer to FIGS. 1 to 3.

FIG. 5 illustrates a part of the non-display area NA of the first side of the display device 200 of FIG. 4, and FIG. 6 illustrates a part of the non-display area NA of the second side of the display device 200 of FIG. 4.

For example, the first side may refer to an upper side of the display device 200, and the second side may refer to a lower side opposite to the first side.

In FIGS. 5 and 6, for convenience, at least some of the buffer layer (112 in FIG. 2), the gate insulating layer (113 in FIG. 2), and the interlayer insulating layer (114 in FIG. 2) are illustrated as insulating layers 117.

Referring to FIGS. 4 to 6, the first heat transfer member 270 of the second embodiment of the present disclosure may be provided at the edge of the first side non-display area NA between the substrate 111 and the encapsulation substrate 160.

Further, the second heat transfer member 275 of the second embodiment of the present disclosure may be provided at the edge of the second side non-display area NA between the substrate 111 and the encapsulation substrate 160.

In the non-display area NA, at least some layers of the insulating layer 117, that is, the buffer layer 112, the gate insulating layer 113, and the interlayer insulating layer 114 may extend.

For example, the link line LW may be disposed on the substrate 111 in the non-display area NA.

The link line LW may extend from the display area AA to an end of the non-display area NA on the first side.

A plurality of link lines LW may be provided.

Further, a low potential power line shorting bar SB may be disposed in the non-display area NA on the second side.

In this case, the link line LW and the low potential power line shorting bar SB may be formed of a material constituting the light shielding layer and/or the driving element 120 of FIG. 2 in the display area AA, but the present disclosure is not limited thereto.

At least some layers of the insulating layer 117, that is, the buffer layer 112, the gate insulating layer 113, and the interlayer insulating layer 114 may be disposed over the link line LW and the low potential power line shorting bar SB.

Further, the planarization layer 115 may extend to the non-display area NA.

For example, the planarization layer 115 may extend to the non-display area NA so as to be spaced apart from the end of the substrate 111 by a predetermined distance, but is not limited thereto.

Further, the planarization layer 115 may extend from the non-display area NA on the first side to the non-display area NA so as to be spaced apart from the adhesive layer 165 and the end of the encapsulation substrate 160 by a predetermined distance. Also, the planarization layer 115 may extend from the non-display area NA on the second side to the end of the adhesive layer 165 and the encapsulation substrate 160, but is not limited thereto.

The pad electrode PE may be disposed over the insulating layer 117 at an end of the substrate 111.

The pad electrode PE may be electrically connected to the link line LW through a contact hole CH.

The bank 116 may extend to the non-display area NA so as to be spaced apart from the end of the planarization layer 115 by a predetermined distance.

Meanwhile, in the non-display area NA of the first side, a part of the bank 116 may form an outer bank 116' that covers an inner end portion of the pad electrode PE in an island shape. The bank 116 and the outer bank 116' may be separated and disposed on both sides with respect to the trench 180.

Further, in the non-display area NA, the organic layer 132 may be disposed on the bank 116.

In the non-display area NA, the cathode 133 may be disposed on the organic layer 132.

Further, the cathode 133 may extend to the non-display area NA to cover the organic layer 132. For example, the cathode 133 extends into the trench 180 so as to cover the end of the bank 116 in the non-display area NA on the first side, while extending to the non-display area NA so as to cover the bank 116 and the organic layer 132 in the non-display area NA on the second side, while extending to the non-display area NA, but is not limited thereto.

Further, the protection layer 140 may extend to the non-display area NA so as to cover the cathode 133. For example, the protection layer 140 may extend into the trench 180 while covering the cathode 133 in the non-display area NA of the first side, while extending to the non-display area NA so as to cover the cathode 133 in the non-display area NA of the second side.

The encapsulation substrate 160 may be disposed over the protection layer 140 with an adhesive layer 165 interposed therebetween.

Meanwhile, in the display device 200 according to the second embodiment of the present disclosure configured as described above is characterized in that the first heat transfer member 270 is disposed at the edge of the non-display area NA on the first side, and the second heat transfer member 275 is disposed at the edge of the non-display area NA on the second side.

That is, in the display device 200 according to the second embodiment of the present disclosure is characterized in that the first heat transfer member 270 is disposed on the data pad part 107 to transfer heat generated from the pad electrode PE to the encapsulation substrate 160 through the first heat transfer member 270, and the second heat transfer member 275 is disposed above the low potential power line shorting bar SB to transfer heat generated from the low potential power line shorting bar SB to the encapsulation substrate 160 through the second heat transfer member 275. Accordingly, the display device 200 according to the second embodiment of the present disclosure may maintain a more stable temperature than the display device of the first embodiment, and may further contribute to extending the lifespan of the display device 200.

For example, the first heat transfer member 270 may be disposed at the edge of the first side non-display area NA between the substrate 111 and the encapsulation substrate 160, while the second heat transfer member 275 may be disposed at the edge of the second side non-display area NA between the substrate 111 and the encapsulation substrate 160.

For example, a plurality of first heat transfer members 270 may be disposed along the data pad part 107 of the non-display area NA of the first side where relatively much heat is generated. The second heat transfer member 275 may be integrally disposed along the low potential power line shorting bar SB of the non-display area NA of the second side, but is not limited thereto. That is, for another example, the first heat transfer member 270 and the second heat transfer member 275 may be arranged integrally or separately. In addition, the first heat transfer member 270 may be arranged integrally, while the second heat transfer members 275 may be arranged separately.

Further, the first heat transfer member 270 and the second heat transfer member 275 may be configured by any one of gold (Au), silver (Ag), copper (Cu), aluminum (Al), titanium (Ti), molybdenum-titanium alloy (MoTi), and nickel (Ni), but are not limited thereto.

The first heat transfer member 270 of the second embodiment of the present disclosure may include a first heat collecting part 270a disposed over the outer bank 116' and in contact with the outer bank 116', a first heat dissipating part 270b disposed below the encapsulation substrate 160 and in contact with the encapsulation substrate 160, and a first connection part 270c disposed in the adhesive layer 165 and connecting the first heat collecting part 270a and the first heat dissipating part 270b, but is not limited thereto.

The second heat transfer member 275 of the second embodiment of the present disclosure may include a second heat collecting part 275a disposed over the planarization layer 115 and in contact with the planarization layer 115, a second heat dissipation part 275b disposed below the encapsulation substrate 160 and in contact with the encapsulation substrate 160, and a second connection part 275c disposed in the adhesive layer 165 and connecting the second heat collecting part 275a and the second heat dissipation part 275b, but is not limited thereto.

For example, the first heat collecting part 270a may be disposed to overlap with the pad electrode PE.

Further, the first heat collecting part 270a may be disposed on the outer bank 116' and a bottom surface thereof may be substantially parallel to the top surface of the outer bank 116'.

The first connection part 270c may extend from the first heat collecting part 270a so that the surface thereof may have a predetermined angle with respect to the outer bank.

Further, the first heat dissipating part 270b extends from the first connection part 270c, may be disposed below the encapsulation substrate 160, and may have an upper surface that is substantially parallel to a lower surface of the encapsulation substrate 160.

Further, for example, the second heat collecting part 275a may be disposed so as to overlap a part of the low potential power line shorting bar SB. Further, the second heat collecting part 275a may be disposed on the planarization layer 115, and a bottom surface thereof may be substantially parallel to a top surface of the planarization layer 115.

Further, the second connection part 275c extends from the second heat collecting part 275a so that the surface thereof may have a predetermined angle with respect to the planarization layer 115.

Further, the second heat dissipation part 275b extends from the second connection part 275c, is disposed below the encapsulation substrate 160, and has an upper surface that is substantially parallel to a lower surface of the encapsulation substrate 160.

Meanwhile, the second heat dissipation part 275b may be disposed inside the second heat collecting part 275a, but is not limited thereto. However, in this case, as the low potential power line shorting bar SB is disposed to be spaced apart from the adhesive layer 165 and the end of the encapsulation substrate 160 by a predetermined distance, only a part of the second heat collecting part 275a may overlap.

Accordingly, in the present disclosure, the second heat collecting part may be disposed inside the second heat dissipation part, and this will be described in detail with reference to the drawings.

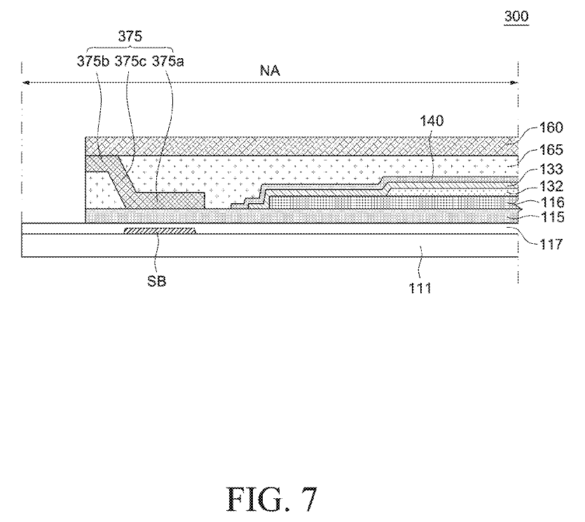

FIG. 7 is a cross-sectional view of a display device according to a third embodiment of the present disclosure.

In the display device 300 of the third embodiment of FIG. 7, only a configuration of the second heat transfer member 375 is different from that of the display device 200 of the second embodiment of FIGS. 4 to 6 described above, and other configurations are substantially the same, so that a redundant description will be omitted. In addition, the same reference numerals will be used for the same components. Hereinafter, description of the same reference numerals may refer to FIG. 1 through FIG. 6.

FIG. 7 illustrates a part of the non-display area NA on the second side.

For example, the second side may mean a lower side of the display device 300.

In FIG. 7, for the convenience of description, at least some of the buffer layer (112 in FIG. 2), the gate insulating layer (113 in FIG. 2), and the interlayer insulating layer (114 in FIG. 2) are illustrated as insulating layers 117.

Referring to FIG. 7, the second heat transfer member 375 according to the third embodiment of the present disclosure may be provided at the edge of the non-display area NA on the second side between the substrate 111 and the encapsulation substrate 160.

In the non-display area NA, at least some layers of the insulating layer 117, that is, the buffer layer 112, the gate insulating layer 113, and the interlayer insulating layer 114 may extend.

A low potential power line shorting bar SB may be disposed in the non-display area NA on the second side.

For example, the low potential power line shorting bar SB may be disposed to be spaced apart from the adhesive layer 165 and the end of the encapsulation substrate 160 by a predetermined distance, but is not limited thereto.

At least some layers of the insulating layer 117 may be disposed on the low potential power line shorting bar SB.

Further, the planarization layer 115 may extend to the non-display area NA.

For example, the planarization layer 115 may extend from the non-display area NA on the second side to ends of the adhesive layer 165 and the encapsulation substrate 160, but is not limited thereto.

Meanwhile, in the display device 300 according to the third exemplary embodiment of the present disclosure configured as described above, the second heat transfer member 375 may be disposed at the edge of the non-display area NA on the second side.

The second heat transfer member 375 may be integrally disposed along the low potential power line shorting bar SB of the non-display area NA of the second side, but is not limited thereto.

The second heat transfer member 375 of the third embodiment of the present disclosure may include a second heat collecting part 375a which is disposed over the planarization layer 115 to be in contact with the planarization layer 115, a second heat dissipating part 375b which is disposed below the encapsulation substrate 160 to be in contact with the encapsulation substrate 160, and a second connection part 375c which is disposed in the adhesive layer 165 to connect the second heat collecting part 375a and the second heat dissipating part 375b, but is not limited thereto.

For example, the second heat collecting part 375a may be disposed to overlap with the entire low potential power line shorting bar SB. Further, the second heat collecting part 375a may be disposed over the planarization layer 115, and a bottom surface thereof may be substantially parallel to an upper surface of the planarization layer 115.

Further, the second connection part 375c extends from the second heat collecting part 375a so that the surface of the second connection part 375c may have a predetermined angle with respect to the planarization layer 115.

In addition, the second heat dissipating part 375b may extend from the second connection part 375c, be disposed below the encapsulation substrate 160, and have an upper surface substantially parallel to the lower surface of the encapsulation substrate 160.

Meanwhile, the second heat collecting part 375a may be disposed more inwardly than the second heat dissipating part 375b, and in this case, the second heat collecting part 375a may overlap with the entire low potential power line shorting bar SB. Accordingly, heat generated from the low potential power line shorting bar SB may be effectively transferred to the encapsulation substrate 160 through the second heat transfer member 375.

Meanwhile, according to the present disclosure, an encapsulation structure of a multilayer structure composed of a sealing member and a reinforcing substrate may be disposed on the protective layer, which will be described in detail with reference to the drawings.

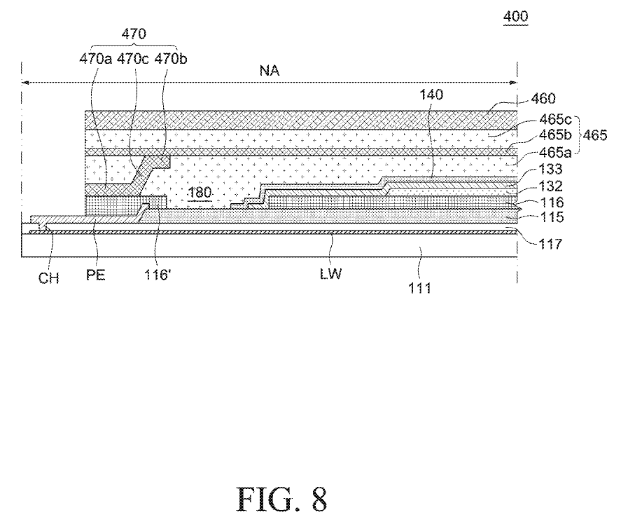

FIG. 8 is a cross-sectional view of a display device according to a fourth embodiment of the present disclosure.

A display device 400 according to the fourth embodiment of FIG. 8 is substantially identical in configuration to the first embodiment of FIGS. 1 to 3 described above, except that an encapsulation structure of a multilayer structure composed of a sealing member 465 and a reinforcing substrate 460 is applied. Therefore, repeated descriptions of the identical components will be omitted. In addition, the same reference numerals will be used for the same components. Hereinafter, description of the same reference numerals may refer to FIG. 1 through FIG. 7.

Referring to FIG. 8, in the display device 400 of the fourth embodiment of the present disclosure, an encapsulation structure of a multilayer structure composed of a sealing member 465 and a reinforcing substrate 460 may be disposed over the protection layer 140.

A small-sized display panel used in a mobile device and a portable device has a small area of the display panel so that heat generation in an element is rapidly emitted and there is less problem of bonding. However, in a large-sized display panel used in a monitor, tablet, or television receiver, the area of the display panel is large, so that an encapsulation structure for an optimal heat dissipation effect and bonding force is required.

In addition, in order to secure insufficient rigidity, the display device may further include a separate inner plate on the encapsulation substrate. In this case, it is necessary to secure a space for disposing a separate inner plate, and there is a problem in that there is a limitation in slimming and lightening of the display device due to the weight of the inner plate. In addition, there is a limitation in that a vertical space is generated by an air gap generated between the encapsulation substrate and the inner plate as much as the thickness of the adhesive tape disposed to adhere the encapsulation substrate and the inner plate, thereby deteriorating heat dissipation performance.

Accordingly, in the fourth embodiment of the present disclosure, a reinforcing substrate 460 having a relatively large thickness may be fixed while removing a separate inner plate, and an encapsulation structure of a multilayer structure including a sealing member 465 capable of preventing process defects is applied.

For example, the sealing member 465 according to the fourth exemplary embodiment of the present disclosure may include a first adhesive layer 465a facing the substrate 111, a second adhesive layer 465c facing the reinforcing substrate 460, and a barrier layer 465b disposed between the first adhesive layer 465a and the second adhesive layer 465c.

In this case, each of the first adhesive layer 465a and the second adhesive layer 465c may be made of a polymer material having adhesiveness. For example, the first adhesive layer 465a may be made of any one of olefin-based, epoxy-based, and acrylate-based polymer materials. In addition, the second adhesive layer 465c may be made of any one of olefin-based, epoxy-based, acrylate-based, amine-based, phenol-based, and acid anhydride-based polymeric materials that do not contain carboxyl groups.

For heat dissipation of the substrate 111, at least the first adhesive layer 465a of the first and second adhesive layers 465a and 465c may be formed of a mixture including particles of an adhesive polymer material and a metal material. For example, the particles of the metal material may be powder made of nickel (Ni).

The above configuration may improve the rate at which the driving heat generated in the substrate 111 may be dissipated through the sealing member 465, thereby enhancing the heat dissipation effect on the substrate 111.

In addition, in order to prevent moisture permeation, the first adhesive layer 465a may be formed of a mixture further including a hygroscopic inorganic filler. The hygroscopic inorganic filler may be at least one of barium oxide (BaO), calcium oxide (CaO), and magnesium oxide (MgO).

In addition, since the first adhesive layer 465a and the second adhesive layer 465c are formed in a multi-layered structure, there is an advantage in that the reliability to reduce the warpage phenomenon in which the display panel is bent may also be improved.

The barrier layer 465b may be made of any one of a metal material and an inorganic insulating material. That is, the barrier layer 465b may include a metal material such as Al, Cu, Sn, Ag, Fe, Zn and the like. In another example, the barrier layer 465b may be formed of a thin film of an inorganic insulating material such as SiOₓ and SiONₓ.

Since the sealing member 465 according to the fourth embodiment of the present disclosure includes first and second adhesive layers 465a and 465c separated by a barrier layer 465b, it may be implemented to have a thickness approximately twice as thick as the adhesive material of the single layer without a process defect. Accordingly, since the reinforcing substrate 460 fixed by the sealing member 465 may be provided with a thick thickness, there is an advantage in that the increase in rigidity and the improvement in the heat dissipation effect may be easily realized.

For example, the reinforcing substrate 460 may be made of any one of glass, metal, and plastic polymers. For example, the reinforcing substrate 460 may be made of a metal material including components of Al, Cu, Sn, Ag, Fe, or Zn.

Meanwhile, in the fourth exemplary embodiment of the present disclosure, the first heat transfer member 470 of the fourth exemplary embodiment of the present disclosure may be provided at the edge of the first side non-display area Na between the substrate 111 and the barrier layer 465b.

The first heat transfer member 470 of the fourth embodiment of the present disclosure may include a first heat collecting part 470a which is disposed on the outer bank 116' and in contact with the outer bank 116', a first heat dissipation part 470b which is disposed below the barrier layer 465b and in contact with the barrier layer 465b, and a first connection part 470c which is disposed in the first adhesive layer 465a and connecting the first heat collecting part 470a and the first heat dissipation part 470b, but is not limited thereto.

For example, the first heat collecting part 470a may be disposed to overlap with the pad electrode PE.

Further, the first heat collecting part 470a may be disposed on the outer bank 116' and a lower surface thereof may be substantially parallel to an upper surface of the outer bank 116'.

The first connection part 470c extends from the first heat collecting part 470a so that the surface thereof may have a predetermined angle with respect to the outer bank 116'.

The first heat dissipation part 470b extends from the first connection part 470c, is disposed below the barrier layer 465b, and an upper surface of the first heat dissipation part 470b may be substantially parallel to a bottom surface of the barrier layer 465b.

The exemplary embodiments of the present disclosure can also be described as follows:

A display device according to an exemplary embodiment of the present disclosure may include a substrate including a display area and a non-display area outside the display area, a planarization layer disposed over the substrate and extending from the display area to the non-display area, a bank disposed over the planarization layer and extending to the non-display area, a protection layer disposed over the bank, an adhesive layer disposed over the protection layer and disposed in the adhesive layer along at least one edge of the encapsulation substrate and the non-display area, and a heat transfer member extending from an upper surface of the substrate to the encapsulation substrate and transferring heat.

The display device may further include a link line disposed over the substrate in the non-display area on a first side.

The display device may further include an insulating layer disposed over the link line and a contact hole through which a portion of the insulating layer is removed to expose a portion of the upper surface of the link line.

The display device may further include a low potential power line shorting bar disposed over the substrate in the non-display area on a second side.

The planarization layer may extend into the non-display area, extending a predetermined distance away from the adhesive layer and an end portion of the encapsulation substrate in the non-display area on the first side, and extending to the adhesive layer and the end portion of the encapsulation substrate in the non-display area on the second side.

The display device may further include a pad electrode disposed over the insulating layer at an end portion of the substrate, the pad electrode may be electrically connected to the link line through the contact hole.

In the non-display area of the first side, a part of the bank may constitute an outer bank that covers an inner end portion of the pad electrode in an island shape, and the bank and the outer bank may be separated and disposed on both sides with respect to the trench.

The display device may further include an organic layer disposed over the bank in the non-display area and a cathode disposed on the organic layer, the cathode may extend into the trench to cover an end portion of the bank in the non-display area on the first side, while extending from the non-display area on the second side to the non-display area to cover the bank and the organic layer.

The display device may further include a protective layer extending into the non-display area to cover the cathode in the non-display area of the first side and to cover the cathode in the non-display area of the second side.

The heat transfer member may include a first heat transfer member disposed at an edge of the non-display area on a first side and a second heat transfer member disposed at an edge of the non-display area on a second side.

The first heat transfer member is disposed in plurality along the data pad part of the non-display area of the first side, and the second heat transfer member may be integrally disposed along the low potential power line shorting bar of the non-display area of the second side.

The first heat transfer member and the second heat transfer member may be each configured from any one of copper (Cu), aluminum (Al), titanium (Ti), gold (Au), silver (Ag), molybdenum-titanium alloy (MoTi), and nickel (Ni).

The first heat transfer member may include a first heat collecting part disposed over the outer bank to be in contact with the outer bank, a first heat dissipation unit disposed below the encapsulation substrate to be in contact with the encapsulation substrate, and a first connection unit disposed in the adhesive layer to connect the first heat collecting part and the first heat dissipation unit.

The first heat collecting part may be disposed to overlap with the pad electrode, and a lower surface of the first heat collecting part may be parallel to an upper surface of the outer bank.

The first connection part may extend from the first heat collecting part so that a surface thereof may be disposed to be inclined with respect to the outer bank.

The first heat dissipation part above extends from the first connection part above, and an upper surface may be parallel to a lower surface of the encapsulation substrate above.

The second heat transfer member may include a second heat collecting part disposed over the planarization layer and configured to be in contact with the planarization layer, a second heat dissipation part disposed below the encapsulation substrate and configured to be in contact with the encapsulation substrate, and a second connection part disposed in the adhesive layer and connecting the second heat collecting part and the second heat dissipation part.

The second heat collecting part may be disposed to overlap with the low potential power line shorting bar, and a lower surface of the second heat collecting part may be parallel to an upper surface of the planarization layer.

The second connection part may extend from the second heat collecting part and may have a surface inclined with respect to the planarization layer.

The second heat dissipation part above extends from the second connection part above, and an upper surface may be parallel to a lower surface of the encapsulation substrate above.

Although the exemplary embodiments of the present disclosure have been described in detail with reference to the accompanying drawings, the present disclosure is not limited thereto and may be embodied in various forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate comprising a display area and a non-display area positioned outside the display area;
a planarization layer disposed over the substrate, wherein the planarization layer extends from the display area to the non-display area;
a bank disposed over the planarization layer, wherein the bank extends to the non-display area;
a protection layer disposed over the bank;
an adhesive layer and an encapsulation substrate disposed over the protection layer; and
a heat transfer member disposed on the adhesive layer along at least one edge of the non-display area, wherein the heat transfer member extends from an upper surface of the substrate to the encapsulation substrate for transferring heat.

2. The display device according to claim 1, further comprising:
a link line disposed over the substrate in the non-display area, wherein the link line is disposed on a first side of the non-display area.

3. The display device according to claim 2, further comprising:
an insulating layer disposed over the link line; and
a contact hole through which a part of a region of the insulating layer is removed to expose a part of an upper surface of the link line.

4. The display device according to claim 3, further comprising:
a low potential power line shorting bar disposed over the substrate in the non-display area, wherein the low potential power line shorting bar is disposed on a second side of the non-display area.

5. The display device according to claim 4, wherein the planarization layer extends into the non-display area, wherein the planarization layer extends a predetermined distance away from the adhesive layer and an end portion of the encapsulation substrate on the first side of in the non-display area, and wherein the planarization layer extends to the adhesive layer and the end portion of the encapsulation substrate on the second side of the non-display area.

6. The display device according to claim 4, further comprising:
a pad electrode disposed over the insulating layer at an end portion of the substrate,
wherein the pad electrode is electrically connected to the link line through the contact hole.

7. The display device according to claim 6, wherein a part of the bank on the first side of the non-display area constitutes an outer bank which covers an inner end portion of the pad electrode in an island shape,
wherein the bank and the outer bank are separated, and
wherein the bank and the outer bank are disposed on both sides with respect to a trench.

8. The display device according to claim 7, further comprising:
an organic layer disposed over the bank in the non-display area; and
a cathode disposed on the organic layer,
wherein the cathode extends from the first side of the non-display area into the trench so as to cover the end portion of the bank, and
wherein the cathode extends from a second side of the non-display area to the non-display area so as to cover the bank and the organic layer.

9. The display device according to claim 8, further comprising:
a protective layer extending into the trench,
wherein the protective layer covers the cathode on the first side of the non-display area, and
wherein the protective layer extends from the second side of the non-display area to the non-display area so as to cover the cathode.

10. The display device according to claim 7, wherein the heat transfer member comprises:
a first heat transfer member disposed at an edge of the first side of the non-display area; and
a second heat transfer member disposed at an edge of the second side of the non-display area.

11. The display device according to claim 10, wherein a plurality of the first heat transfer members is disposed along a data pad part of the first side of the non-display area, and
wherein the second heat transfer member is integrally disposed along the low potential power line shorting bar of the second side of the non-display area.

12. The display device according to claim 10, wherein the first heat transfer member and the second heat transfer member are each configured from any one of copper (Cu), aluminum (Al), titanium (Ti), gold (Au), silver (Ag), molybdenum-titanium alloy (MoTi), and nickel (Ni).

13. The display device according to claim 10, wherein the first heat transfer member comprises:
a first heat collecting part disposed over the outer bank, wherein the first heat collecting part is configured to be in contact with the outer bank;
a first heat dissipation part disposed below the encapsulation substrate, wherein the first heat dissipation part is configured to be in contact with the
encapsulation substrate; and
a first connection part disposed in the adhesive layer, wherein the first connection part is configured to connect the first heat collecting part and the first heat dissipation part.

14. The display device according to claim 13, wherein the first heat collecting part is disposed to overlap with the pad electrode, and
wherein the first heat collecting part has a lower surface parallel to an upper surface of the outer bank.

15. The display device according to claim 13, wherein the first connection part extends from the first heat collecting part, and wherein the first connection part has a surface disposed to be inclined with respect to the outer bank.

16. The display device according to claim 13, wherein the first heat dissipation part extends from the first connection part, and wherein the first heat dissipation part has an upper surface parallel to a lower surface of the encapsulation substrate.

17. The display device according to claim 10, wherein the second heat transfer member comprises:
a second heat collecting part disposed over the planarization layer, wherein the second heat collecting part is configured to be in contact with the planarization layer;
a second heat dissipation part disposed below the encapsulation substrate, wherein the second heat dissipation part is configured to be in contact with the encapsulation substrate; and
a second connection part disposed in the adhesive layer, wherein the second connection part connects the second heat collecting part and the second heat dissipation part.

18. The display device according to claim 17, wherein the second heat collecting part is disposed to overlap with the low potential power line shorting bar, and
wherein the second heat collecting part has a lower surface parallel to an upper surface of the planarization layer.

19. The display device according to claim 17, wherein the second connection part extends from the second heat collecting part, and wherein the second connection part has a surface inclined with respect to the planarization layer.

20. The display device according to claim 17, wherein the second heat dissipation part extends from the second connection part, and wherein the second heat dissipation part has an upper surface parallel to a lower surface of the encapsulation substrate.
